(19) United States
(12) Patent Application Publication
(10) Pub. No.: US 2012/0217856 A1
(43) Pub. Date: Aug. 30, 2012

(54) ELECTRONIC DEVICE ENCLOSURE FOR RECEIVING STORAGE DEVICE

(75) Inventors: YUN-LUNG CHEN, Tu-Cheng (TW); LIANG-CHIN WANG, Tu-Cheng (TW); JIAN HU, Wuhan City (CN); YU-MING XIAO, Wuhan City (CN); HAI-QING ZHU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/326,413

(22) Filed: Dec. 15, 2011

(30) Foreign Application Priority Data
Feb. 25, 2011 (CN) 201110046312.2

(51) Int. Cl. H05K 5/02

(52) U.S. Cl. 312/327

(57) ABSTRACT

An electronic device with a storage device enclosure is disclosed. The electronic device enclosure comprises a chassis comprising a bottom plate and a side plate substantially perpendicular to the bottom plate; a securing member attached to the side plate and comprising a plurality of positioning slots; a bracket rotatably attached to the side plate about a pivoting axis substantially parallel to the bottom plate relative to the chassis; the bracket comprising a side panel substantially perpendicular to the side plate; a blocking portion located on the side panel, and the blocking portion being elastic and engaged in one of the plurality of positioning slots.

### BACKGROUND

1. Technical Field

The present disclosure relates to electronic device enclosures, and more particularly, to a storage device enclosure.

2. Description of Related Art

A typical personal computer includes data storage devices such as a hard disk drive (HDD), a floppy disk drive, and a compact disc-read only memory (CD-ROM) drive. Many data storage devices are attached to a bracket of a computer enclosure using screws. A tool such as a screwdriver is used to fasten/unfasten the screws when installing/removing the data storage devices from the bracket. Such operations are laborious and time-consuming. Furthermore, accidents may occur during operations (i.e. operator dropping tools and screws). When such an accident occurs, other internal components of the computer may be damaged as a result.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of an electronic device enclosure in accordance with an embodiment.

FIG. 2 is similar to FIG. 1, but shows in a different aspect.

FIG. 3 is an assembled view of FIG. 1, and a bracket of the electronic device is located in a first position.

FIG. 4 is similar to FIG. 3, but the bracket is located in a second position.

FIG. 5 is an enlarged view of circled portion V of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

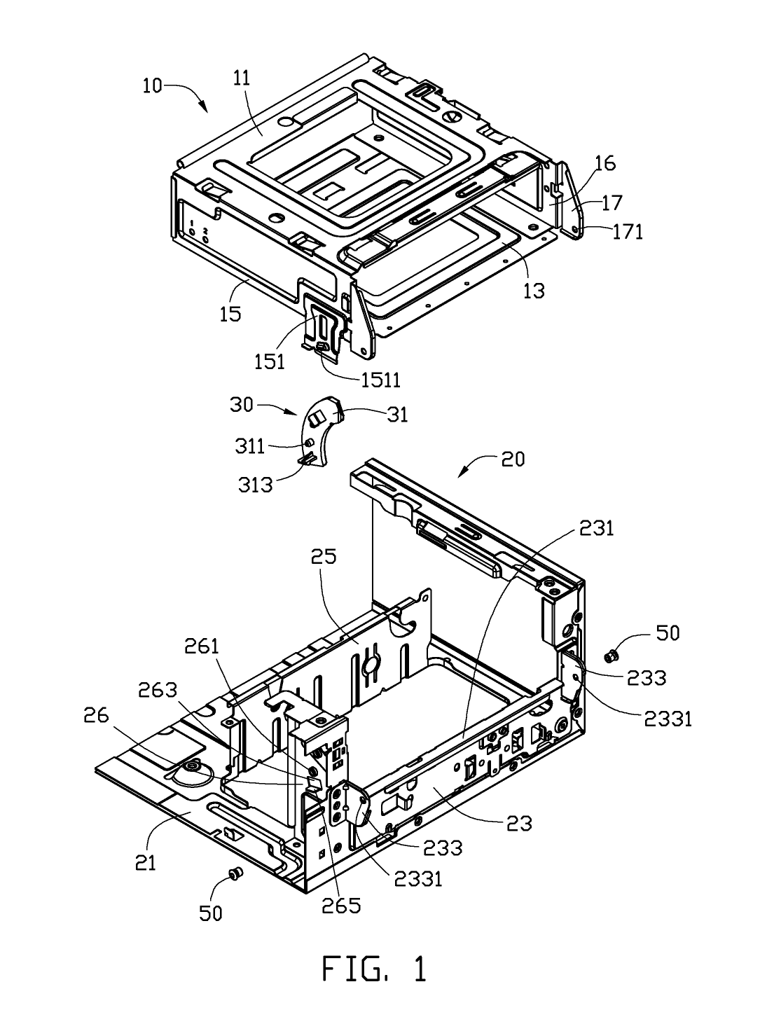

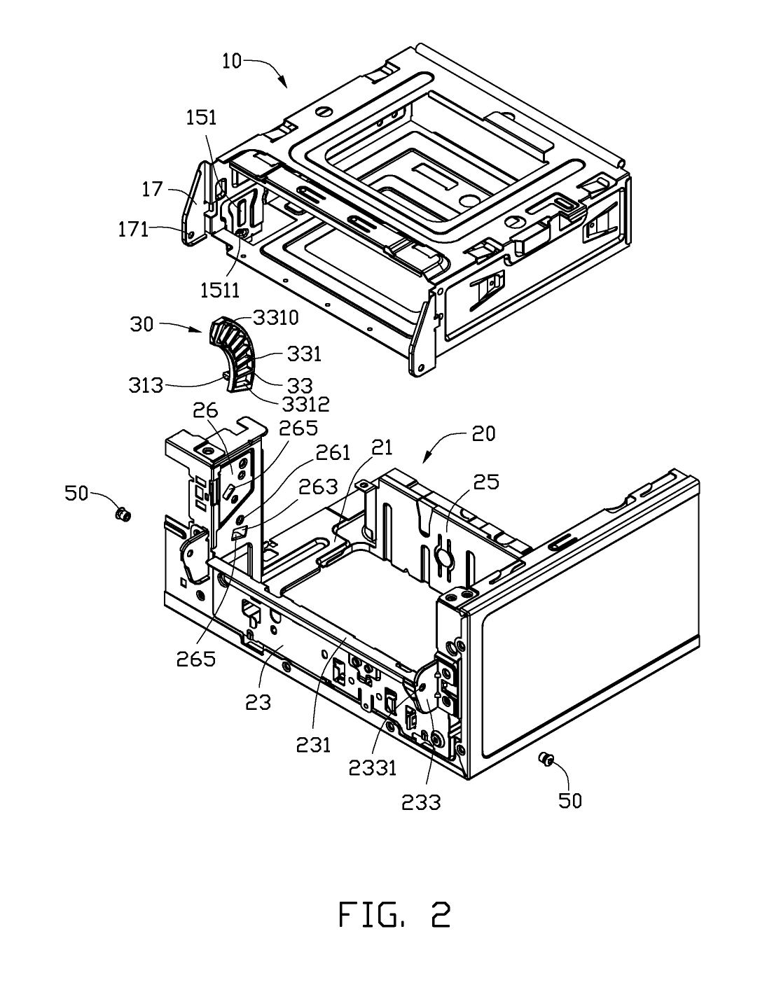

Referring to FIGS. 1-2, an electronic device enclosure in accordance with an embodiment comprises a bracket 10, a chassis 20 and a securing member 30.

The bracket 10 comprises a top panel 11, and a bottom panel 13 opposite to the top panel 11, a first side panel 15 and a second side panel 16. In one embodiment, the first side panel 15 is substantially parallel to the second side panel 16 and perpendicular to the bottom panel 13. The top panel 11, the bottom panel 13, and the first and second side panels 15, 16 cooperatively define a receiving space for housing a storage device. The storage device may be a hard disk drive.

A blocking piece 151 extends from a bottom edge of the first side panel 15 in a direction substantially perpendicular to the bottom panel 13. A blocking portion 1511 protrudes from an outer surface of the blocking piece 151. In one embodiment, the blocking piece 151 is elastic. Two mounting panels 17 respectively extend from a front edge of the first and second panels 15, 16, each defining a mounting hole 171.

The chassis 20 comprises a bottom plate 21 and a side plate 23 substantially perpendicular to the bottom plate 21. A supporting plate 25 is located on the bottom plate 21 substantially parallel to the side plate 23. An opening 231 is defined in the side plate 23, for receiving the bracket 10.

A securing plate 26 extends from the side plate 23. In one embodiment, the securing plate 26 is substantially perpendicular to the side plate 23. Two securing holes 261 and two through holes 263, adjacent to each of the two securing holes 261, are defined in the securing plate 26. A retaining tab 265 extends from each of the two through holes 263 located on an outer surface of the securing plate 26. Two fixing pieces 233 extend from opposite edges of the opening 231. In one embodiment, each of the two fixing pieces 233 is substantially perpendicular to the side plate 23 and defines a fixing hole 2331 corresponding to the mounting hole 171.

The securing member 30 comprises a first side 31 and a second side 33 opposite to the first side 31. Two protrusions 311 and two clipping portions 313 are located on the first side 31. The two protrusions 311 are located between the two clipping portions 313. A plurality of positioning slots 331 is defined in the second side 33 for receiving the blocking portion 1511. In one embodiment, the plurality of positioning slots 331 is arranged at an arc.

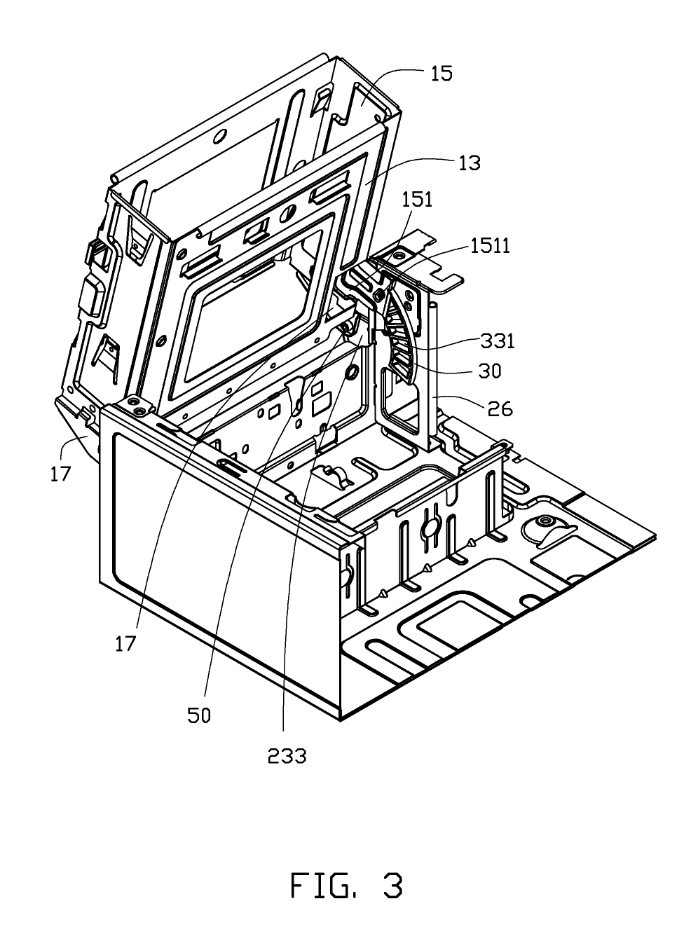

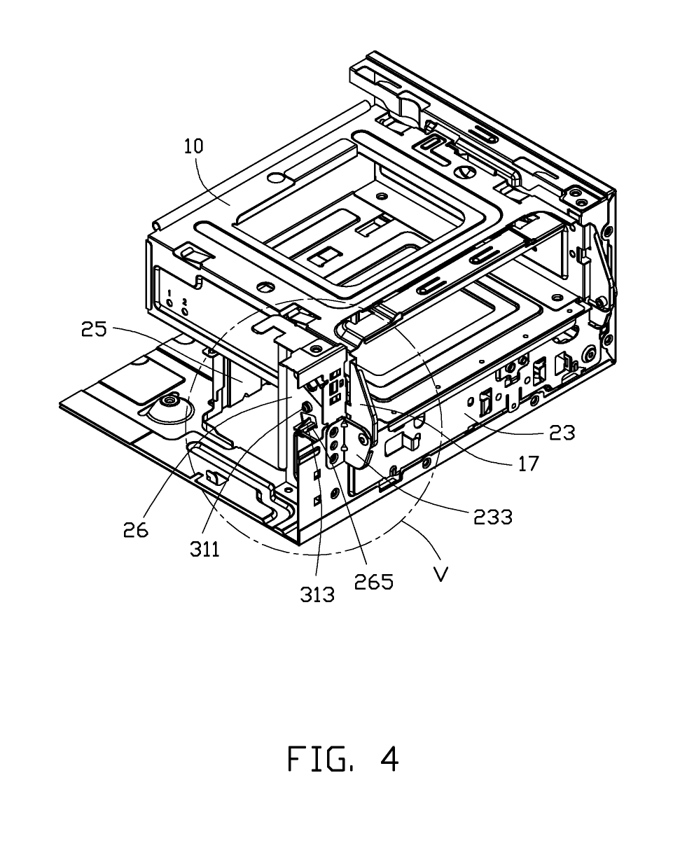

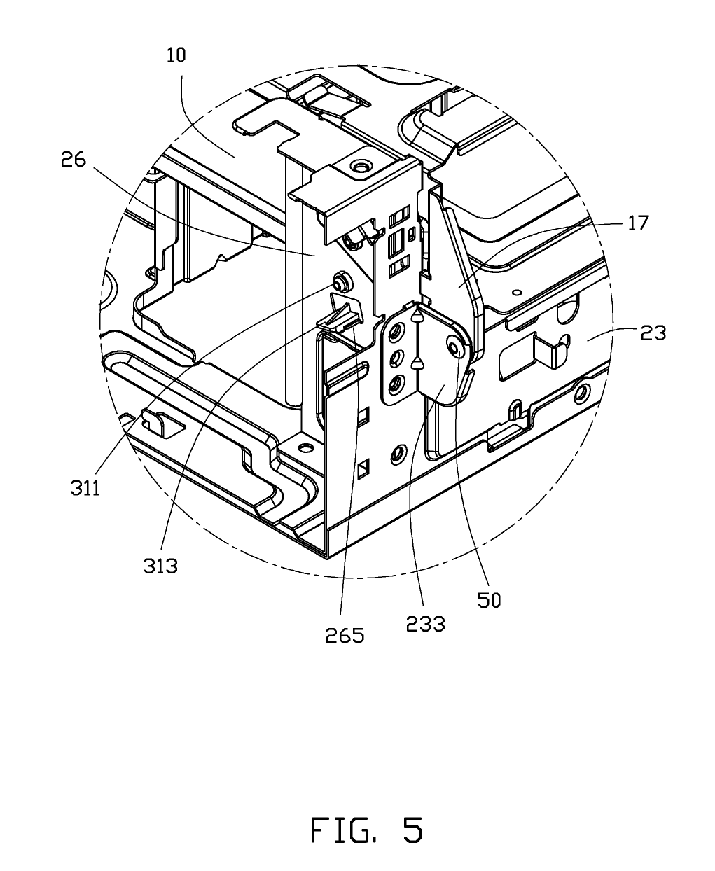

Referring to FIGS. 3-5, the two clipping portions 313 are aligned with the two through holes 263, and the two protrusions 311 are aligned with the two securing holes 261. The securing member 30 is moved towards the securing plate 26. The two clipping portions 313 are passed through the two through holes 263 and are deformed by the retaining tabs 265. The securing member 30 is further moved, the two protrusions 311 are engaged in the two securing holes 261. The two clipping portions 313 are released when extend through the retaining tabs 265, to engage with the retaining tabs 265. Therefore, the securing member 30 is mounted to the securing plate 26.

The bracket 10 is placed in the opening 231 and is sandwiched between the two fixing pieces 233. The fixing holes 2331 are aligned with the mounting holes 171. Two pivoting members 50 are engaged in the fixing holes 2331 and the mounting holes 171, to rotatably secure the bracket 10 to the chassis 20. The bracket 10 is rotated about a pivoting axis shaped by the two pivoting members 50 anticlockwise, until the blocking portion 1511 abuts the securing member 30 to be deformed. In one embodiment, the pivoting axis of the bracket 10 is substantially parallel to the bottom plate 21. The bracket 10 is further rotated anticlockwise, until the blocking portion 1511 is deformed to be received in a top one 3310 of the plurality of positioning slots 331. The bracket 10 is further rotated anticlockwise, the blocking portion 1511 extends through the plurality of positioning slots 331, until being received in the bottom one 3312 of the plurality of positioning slots 331. At this position, the bottom panel 13 is substantially parallel to the bottom plate 21, and the supporting plate 25 abuts a bottom surface of the bottom panel 13. Therefore, the bracket 10 is secured to the chassis 20, to receive the storage device. In one embodiment, the blocking portion 1511 can be received in any one of the plurality of positioning slots 331.

When the bracket 10 needs to be detached from the chassis 20, the bracket 10 is rotated about the pivoting axis clockwise, to disengage the blocking portion 1511 from the bottom one 3312 of the plurality of positioning slots 331. The bracket 10 is further rotated clockwise, until the blocking portion 1511 is removed from the top one 3310 of the plurality of positioning slots 331. Therefore, the bracket 10 can be easily detached from the chassis 20.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. An electronic device enclosure, comprising:
a chassis comprising a bottom plate and a side plate substantially perpendicular to the bottom plate;
a securing member attached to the side plate and comprising a plurality of positioning slots;
a bracket rotatably attached to the side plate about a pivoting axis substantially parallel to the bottom plate relative to the chassis; the bracket comprising a side panel substantially perpendicular to the side plate; a blocking portion located on the side panel, and the blocking portion being elastic and engaged in one of the plurality of positioning slots.

2. The electronic device enclosure of claim 1, wherein a blocking piece extends from a bottom edge of the side panel, and the blocking portion is located on an outer surface of the blocking piece.

3. The electronic device enclosure of claim 1, wherein the plurality of positioning slots is arranged at an arc.

4. The electronic device enclosure of claim 1, wherein the chassis further comprises a securing plate substantially perpendicular to the side plate, and the securing member is attached to the securing plate.

5. The electronic device enclosure of claim 4, wherein the securing plate defines a through hole and a retaining tab extends from an edge of the through hole, the securing member comprises a clipping portion, the clipping portion engages with the retaining tab through the through hole, and the clipping portion is deformable.

6. The electronic device enclosure of claim 5, wherein the securing member comprises a first side and a second side opposite to the first side, the clipping portion is located on the first side, and the plurality of positioning slots is located on the second side.

7. The electronic device enclosure of claim 1, wherein the chassis further comprises a fixing piece extending from an outer surface of the side plate, the bracket comprises a mounting panel extending from the side panel, and the bracket is rotatably engaged with the chassis with the mounting piece rotatably attached to the fixing piece.

8. The electronic device enclosure of claim 7, wherein an opening is defined in the side plate, and the bracket is engaged in the opening.

9. The electronic device enclosure of claim 1, wherein the chassis comprises a supporting plate connected to the bottom plate, and the supporting plate abuts a bottom surface of a bottom panel of the bracket.

10. The electronic device enclosure of claim 9, wherein the supporting plate is substantially perpendicular to the bottom plate and parallel to the side plate.

11. An electronic device enclosure, comprising:
a chassis comprising a bottom plate, a side plate substantially perpendicular to the bottom plate, and a securing plate substantially perpendicular to the side plate; a securing member attached to the securing plate and comprising a plurality of positioning slots, the plurality of positioning slots comprising at least a top positioning slot and a bottom positioning slot;
a bracket rotatably attached to the side plate; the bracket comprising a side panel attached to the securing plate and a bottom panel connected to the side panel; a blocking portion located on the side panel and is adapted to engage in one of the plurality of positioning slots, and the blocking portion is elastic;
wherein the bracket is rotatable about a pivoting axis substantially parallel to the bottom plate relative to the chassis between a first position and a second position; when the bracket is located in the first position, an acute angle is defined between the bottom panel and the bottom plate with the blocking portion engaged in the top positioning slot; when the bracket is located in the second position, the bottom panel is substantially parallel to the bottom plate with the blocking portion engaged in the bottom positioning slot.

12. The electronic device enclosure of claim 11, wherein a blocking piece extends from a bottom edge of the side panel, and the blocking portion is located on an outer surface of the blocking piece.

13. The electronic device enclosure of claim 11, wherein the plurality of positioning slots is arranged at an arc.

14. The electronic device enclosure of claim 11, wherein the securing plate defines a through hole and a retaining tab extends from an edge of the through hole, the securing member comprises a clipping portion, the clipping portion engages with the retaining tab through the through hole, and the clipping portion is deformable.

15. The electronic device enclosure of claim 14, wherein the securing member comprises a first side and a second side opposite to the first side, the clipping portion is located on the first side, and the plurality of positioning slots is located on the second side.

16. The electronic device enclosure of claim 11, wherein the chassis further comprises a fixing piece extending from an outer surface of the side plate, the bracket comprises a mounting panel extending from the side panel, and the bracket is rotatably engaged with the chassis with the mounting piece rotatably attached to the fixing piece.

17. The electronic device enclosure of claim 16, wherein an opening is defined in the side plate, and the bracket is engaged in the opening.

18. The electronic device enclosure of claim 11, wherein the chassis comprises a supporting plate connected to the bottom plate, and the supporting plate abuts a bottom surface of the bottom panel.

19. The electronic device enclosure of claim 18, wherein the supporting plate is substantially perpendicular to the bottom plate and parallel to the side plate.
